(19) United States
(12) Patent Application Publication
(10) Pub. No.: US 2019/0035982 A1
(43) Pub. Date: Jan. 31, 2019

(54) LIGHT SOURCE AND OUTDOOR ILLUMINATION APPARATUS

(71) Applicant: PANASONIC INTELLECTUAL PROPERTY MANAGEMENT CO., LTD., Osaka (JP)

(72) Inventor: Naoko TAKEI, Osaka (JP)

(73) Assignee: PANASONIC INTELLECTUAL PROPERTY MANAGEMENT CO., LTD., Osaka (JP)

(21) Appl. No.: 16/043,454

(22) Filed: Jul. 24, 2018

(30) Foreign Application Priority Data
Jul. 26, 2017 (JP) 2017-144313

(51) Int. Cl. H01L 33/50; F21S 8/08; F21V 9/06; H01L 33/48

(52) U.S. Cl. CPC H01L 33/504; F21S 8/086; F21V 9/06; F21Y 2115/10; H01L 33/507; H01L 33/486; H01L 33/505

(57) ABSTRACT

A road light includes a light source which emits white light having a correlated color temperature of 5000 K˜6500 K, a color deviation within ±10, an S/P ratio, which is a ratio between a light flux in a scotopic vision and a light flux in a photopic vision, of greater than or equal to 2.0, and a lumen equivalence, calculated by Equation 1, of greater than or equal to 3001 m/W. The light source includes a solid-state light emitting element which emits light of a light emission peak wavelength of 380 nm˜430 nm, and a fluorescent material which absorbs the light emitted from the solid-state light emitting element and irradiates the white light.

### CROSS REFERENCE TO RELATED APPLICATION

The entire disclosure of Japanese Patent Application No. 2017-144313 filed on Jul. 26, 2017, including the specification, claims, drawings, and abstract, is incorporated herein by reference in its entirety.

### TECHNICAL FIELD

The present disclosure relates to a light source, and to an outdoor illumination apparatus.

### BACKGROUND

For outdoor illumination apparatuses such as a road light, a vehicle illumination apparatus, or the like, securing visibility of a pedestrian walking on the road, a driver of the traveling vehicle, or the like, is required. A visual sensitivity of humans differs among a photopic vision, a scotopic vision, and a mesopic vision. In a photopic vision (under bright environment), color can be recognized by an action of a cone cell. In the scotopic vision (under dark environment), because the cone cell does not function, the color cannot be recognized, but the visual sensitivity is improved by an action of a rod cell.

The mesopic vision (under dim light environment) is an intermediate state between the photopic vision and the scotopic vision, and in the mesopic vision, both the cone cell and the rod cell function. The brightness in which the vision of humans becomes the mesopic vision is known to be about 0.01-101×. With a brightness greater than this value, the vision becomes photopic, and with a lower brightness, the vision becomes scotopic.

Under a dark environment, a peak of the visual sensitivity is shifted to a side of a shorter wavelength, compared to the bright environment. Such a phenomenon is known as a Purkinje phenomenon. In addition, while the cone cells are present in a large number at a side of a center of a retina, and the number is significantly reduced at regions away from the center side, the rod cells do not exist at the center side of the retina, and the number thereof is rapidly increased at regions away from the center. Because of this, in the mesopic vision, in many cases, the driver of the traveling vehicle views a roadway side of the road with a central vision and a pedestrian way side of the road with a peripheral vision.

In the related art, outdoor illumination apparatus are known which use the Purkinje phenomenon described above (for example, refer to Japanese Unexamined Patent Application Publication No. 2008-091232 A). An illumination apparatus described in Japanese Unexamined Patent Application Publication No. 2008-091232 A includes a roadway side light source unit which illuminates light onto the roadway and a pedestrian way side light source unit which illuminates light onto the pedestrian way. The roadway side light source unit illuminates onto the roadway light adjusted for a peak (555 nm) of the visual sensitivity by the cone cells which actively act in a bright location. On the other hand, the pedestrian way side light source unit illuminates onto the pedestrian way light adjusted for a peak (507 nm) of the visual sensitivity by the rod cells which actively act in a dark location. Because in many cases, the driver views the pedestrian way side of the road with the peripheral vision as described above, when the light adjusted for the visual sensitivity of the rod cells is illuminated onto the pedestrian way side, the visibility of the pedestrian way side is also improved.

However, in the illumination apparatus of Japanese Unexamined Patent Application Publication No. 2008-091232 A, the colors of the lights illuminated by the roadway side light source unit and the pedestrian way side light source unit differ from each other, and thus, a problem may be considered in which the pedestrian or the like can easily feel color irregularities and may feel awkward. In consideration of this, a method may be considered in which, in order to improve the visibility of the central vision and the peripheral vision using one type of light source, a white light is illuminated by a combination of a blue light emitting element which emits blue light, and a yellow fluorescent material which absorbs and converts a wavelength of a part of the blue light.

In this case, the awkward feeling due to the difference between the white light of the roadway side and the white light of the pedestrian way side which can be particularly easily felt by the pedestrians can be suppressed. However, the white light emitted from such a light source has different orientations for the blue light having a high directionality and emitted from the blue light emitting element and the yellow light irradiated to all directions from the fluorescent material, and thus, at an outer peripheral portion of a range in which the white light is illuminated, the white light is of a relatively low color temperature. With such a white light, the advantage of the improvement of the visibility of the periphery by the action on the rod cells under the mesopic vision is reduced. Therefore, a problem may arise in which, even in the illumination range, the range in which the driver of the traveling vehicle can brightly view is limited, or an optical design of the lighting equipment becomes complicated in order to prevent the low color temperature of the white light at the outer periphery of the illumination range.

An advantage of the present disclosure lies in provision of an outdoor illumination apparatus having a simple structure which does not require a complicated optical design, but having a high visibility over an entire illumination region and a uniform color tone over the entire illumination region.

### SUMMARY

According to one aspect of the present disclosure, there is provided a light source including: a solid-state light emitting element that emits light having a light emission peak wavelength of 380 nm˜430 nm; and a fluorescent material that absorbs the light emitted from the solid-state light emitting element and irradiates white light. The white light includes a correlated color temperature of 5000 K˜6500 K, a color deviation within ±10, an S/P ratio, which is a ratio between a light flux in a scotopic vision and a light flux in a photopic vision, of greater than or equal to 2.0, and a lumen equivalence (LE), calculated by Equation 1, of greater than or equal to 3001 m/W.

$$LE = \frac{K {\int }_{380}^{780} V ( λ ) {Φ}_{e} ( λ ) d λ}{{\int }_{380}^{780} {Φ}_{e} ( λ ) d λ} \qquad ( Equation 1 )$$

In Equation 1, K represents a maximum visual sensitivity (6831 m/W), V(λ) represents a standard visual sensitivity, and Φₑ(λ) represents an illumination spectral distribution.

According to the light source of one aspect of the present disclosure, a superior visibility and a uniform color tone can be obtained over the entire illumination region while having a simple structure which does not require a complicated optical design. When an outdoor illumination apparatus having the light source according to one aspect of the present disclosure is applied to a road light, for example, under a dim light environment such as a town light space or a road space during night time, an illumination space may be realized in which a superior visibility is secured over the entire illumination region including the roadway side and the pedestrian way side, the color tone is uniform, and no awkward feeling is caused.

### BRIEF DESCRIPTION OF DRAWINGS

The figures depict one or more implementations in accordance with the present teaching, by way of example only, not by way of limitation. In the figures, like reference numerals refer to the same or similar elements.

FIG. 1 is a diagram showing an illumination surface of a road light which is an example of an embodiment of the present disclosure.

FIG. 2 is an outer appearance perspective diagram of a road light which is an example of an embodiment of the present disclosure.

FIG. 3 is a diagram showing an internal structure of a road light which is an example of an embodiment of the present disclosure.

FIG. 4 is an outer appearance perspective diagram of a light source which is an example of an embodiment of the present disclosure.

FIG. 5 is a cross-sectional diagram along a line AA of FIG. 4.

FIG. 6 is a cross-sectional diagram of a light source which is another example of the embodiment of the present disclosure.

FIG. 7 is a perspective diagram showing a light source which is another example of the embodiment of the present disclosure.

FIG. 8 is a cross-sectional diagram along a line BB of FIG. 7.

FIG. 9 is a diagram showing a light emission spectrum of a light source of Example 1 of the present disclosure.

FIG. 10 is a diagram showing a light emission spectrum of a light source of Example 2 of the present disclosure.

FIG. 11 is a diagram showing a light emission spectrum of a light source of Comparative Example 1.

FIG. 12 is a diagram showing a light emission spectrum of a light source of Comparative Example 2.

### DESCRIPTION OF EMBODIMENTS

Examples of a light source and an outdoor illumination apparatus according to an embodiment of the present disclosure will now be described in detail with reference to the drawings. Selective combining of constituting elements in a plurality of embodiments described below are conceived of from the beginning. The drawings referred to in the description of the embodiment are schematically described, and thus, a size, a ratio, or the like of the constituting elements drawn in the drawings are to be determined in consideration of the following description. In the present specification, a description of “numerical value A˜numerical value B” means “a numerical value greater than or equal to A and smaller than or equal to B”, unless otherwise noted.

In the following, as an outdoor illumination apparatus having a light source according to the present disclosure, a road light (street light) 100 placed on a surface such as a road or street will be exemplified. The road light 100 is used, for example, on an ordinary road, in a factory, in a parking lot, or the like. However, the outdoor illumination apparatus of the present disclosure is not limited to the road light. The outdoor illumination apparatus of the present disclosure may be applied, for example, as headlights of automobiles and two-wheeled vehicles, illuminations for parks and railroad stations, or the like.

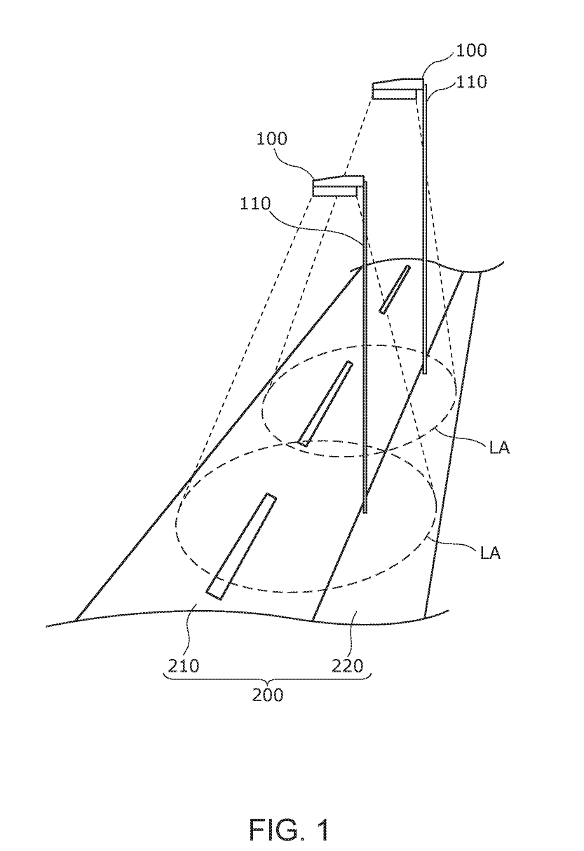

FIG. 1 is a diagram showing an illumination surface of light by the road light 100 which is an example of an embodiment of the present disclosure. As exemplified in FIG. 1, the road light 100 is placed to illuminate white light onto a road 200 having a roadway 210 and a pedestrian way 220. The road light 100 is supported above the road 200 by a pillar-shaped member 110. As shown in FIG. 1, a plurality of the road lights 100 are placed along the road 200 with a predetermined spacing therebetween. The road light 100 illuminates light onto a road surface of the roadway 210 and the pedestrian way 220, and in particular, brightly illuminates an illumination surface LA.

The road light 100 emits white light having a superior visibility under the mesopic vision environment by a light source 310. In addition, the road light 100 illuminates white light having uniform color tone onto the roadway 210 and the pedestrian way 220. The road light 100 is placed, for example, at a height of 5 m˜15 m from the road surface of the road 200. On the road surface of the road 200, desirably, an average horizontal surface illuminance of the illumination surface LA illuminated by the white light is set to 51× or greater. Here, the average horizontal surface illuminance refers to an average illuminance per unit area of the light illuminated onto a horizontal surface.

According to the road light 100, under the mesopic vision environment or photopic vision environment of the illumination range of the light, light having a high visibility for both the pedestrian and the driver is illuminated onto the entire space. In addition, because the light of the road light 100 is illuminated uniformly over the entire illumination region, the pedestrian and the driver do not feel color irregularities, and no awkward feeling is caused.

A spreading angle of the light emitted from the road light 100 is set, for example, to have the average horizontal surface illuminance of 51x or greater, but is desirably set to spread more in a longitudinal direction in which the road 200 extends, than a width direction of the road. In this case, it becomes easy to realize an illumination space having no awkward feeling, by uniform and natural white light. The road light 100 may include a lens which is optically designed such that the light spreads in the longitudinal direction of the road 200.

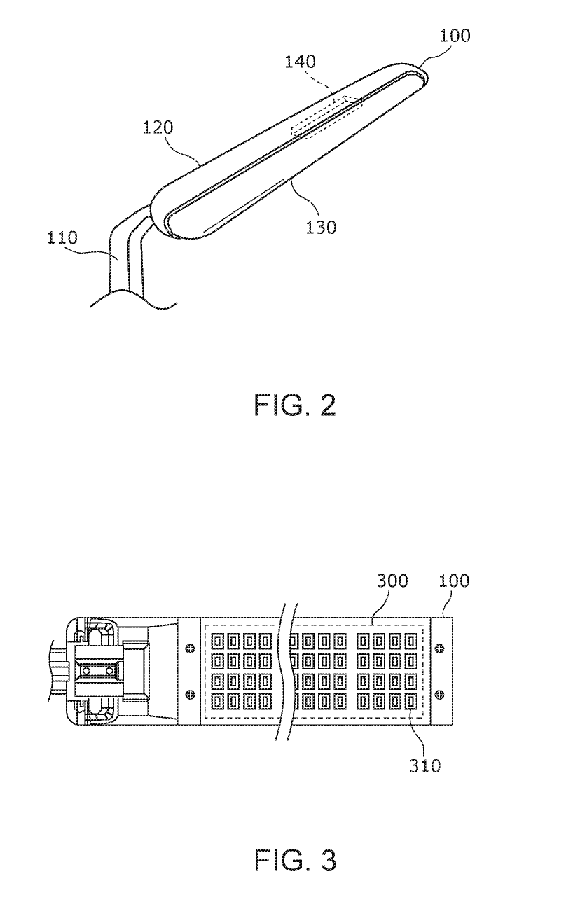

FIG. 2 is an outer appearance perspective diagram of the road light 100. FIG. 3 is a diagram showing an internal structure of the road light 100, and is a diagram showing a state where a light transmissive cover 130 is removed. As exemplified in FIGS. 2 and 3, the road light 100 includes a housing 120, the light transmissive cover 130, and a light emitting unit 300. In addition, the road light 100 may include a power supply unit 140 for supplying electric power to the light source 310. The power supply unit 140 converts, for example, an alternating current electric power of a commercial power supply into a direct current electric power, and outputs the converted electric power to the light source 310. The power supply unit 140 may be built in the road light 100, or may be placed at a location separate from the road light 100.

The housing 120 stores the light emitting unit 300, and holds the light transmissive cover 130 covering the stored light emitting unit 300. The housing 120 is formed, for example, using a metal material, but may alternatively be formed using other materials such as a resin material. In the housing 120, an inner surface may be formed with a light reflective material, in order to improve a usage efficiency of light.

The light transmissive cover 130 is a cover member which is transmissive to the light from the light emitting unit 300, and is attached to the housing 120. The light transmissive cover 130 is formed, for example, from glass, or a transparent resin such as an acrylic resin, polycarbonate, or the like. The light transmissive cover 130 may have a light diffusing property, and may have a function of a lens which is optically designed such that the light spreads in the longitudinal direction in which the road 200 extends.

The light emitting unit 300 illuminates white light onto the road surface of the road 200. The light emitting unit 300 is formed from a plurality of the light sources 310 placed in a matrix form. As will be described in detail later, the light source 310 includes a solid-state light emitting element, and a fluorescent material which converts a wavelength of the light emitted from the light emitting element. It should be noted that a number, placement, or the like, of the light sources 310 of the light emitting unit 300 are not particularly limited.

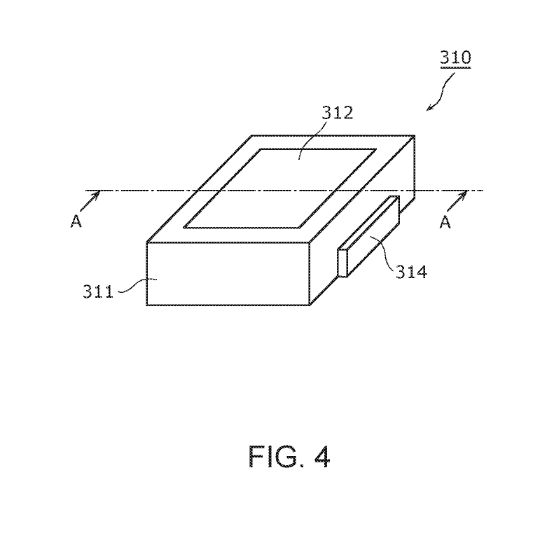

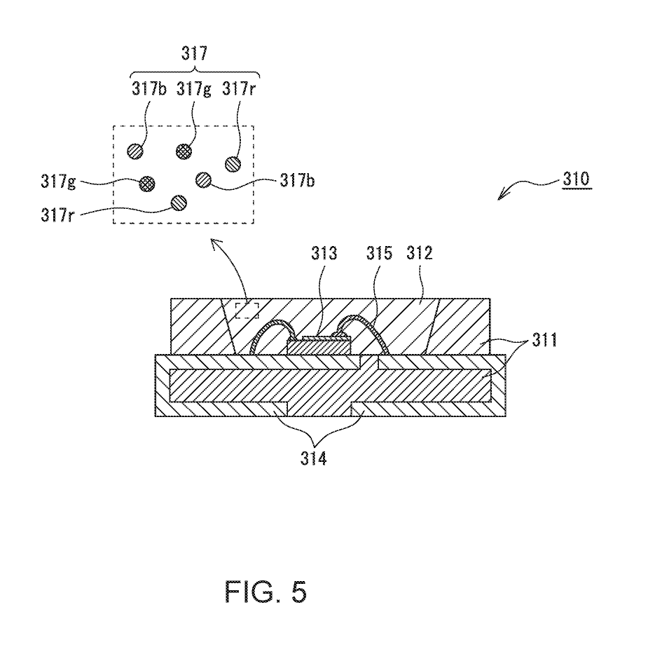

FIG. 4 is an outer appearance perspective diagram of the light source 310, and FIG. 5 is a cross-sectional diagram along a line AA in FIG. 4. As exemplified in FIGS. 4 and 5, the light source 310 is an SMD (Surface Mount Device) type light emitting device. The light source 310 can emit white light which can be felt as bright, in a central vision and a peripheral vision under the mesopic environment. Because of this, the light source 310 is suited for the road light which is used under an environment of dark periphery such as the night time environment. The structure of the light source 310 is not particularly limited, and may be, for example, either an SMD module or a COB (Chip On Board) module.

Here, the peripheral vision refers to visual recognition of a peripheral portion of a field of view having, for example, a viewing angle of 10 degrees or greater, and has a primary active environment under the mesopic or scotopic vision environment. The central vision means, for example, visual recognition of a central portion of a field of view having, for example, a viewing angle of less than 10 degrees, and has a primary active environment under the photopic vision environment.

The light source 310 emits white light having a correlated color temperature of 5000 K˜6500 K, a color deviation (Duv) within ±10, an S/P ratio, which is a ratio of light flux under a scotopic vision to a light flux under photopic vision, of greater than or equal to 2.0, and a lumen equivalence (LE), calculated by Equation 1, of greater than or equal to 3001 m/W.

$$LE = \frac{K {\int }_{380}^{780} V ( λ ) {Φ}_{e} ( λ ) d λ}{{\int }_{380}^{780} {Φ}_{e} ( λ ) d λ} \qquad ( Equation 1 )$$

In Equation 1, K representgs a maximum visual sensitivity (6831 m/W), V(λ) represents a standard visual sensitivity, and Φₑ(λ) represents an illumination spectral distribution.

Desirably, an average rendering index (Ra) of the white light is greater than or equal to 80. When Ra is greater than or equal to 80, a color reproducibility is high, and, for example, color information of a sign placed on and around the road 200 can be more accurately recognized, and the color of the vehicle, the color of the clothing of the pedestrian, or the like can also be accurately understood.

The light source 310 includes a solid-state light emitting element 313 which emits light having a light emission peak wavelength of 380 nm˜430 nm, and a fluorescent material 317 which absorbs at least a part of the light emitted from the light emitting element 313 and irradiates the white light described above. By the use of the light source 310, it becomes possible to illuminate uniform white light which acts on both the cone cell and the rod cell over the entire illumination region, without the need for a complicated optical design. Because of this, for example, during the night time, there is no awkward feeling over the entire illumination space, and both the central vision and the peripheral vision can be perceived as bright.

The light source 310 includes a container 311 having a recess, and a sealing member 312 sealed in the recess. The solid-state light emitting element 313 is mounted in the recess of the container 311. For the solid-state light emitting element 313, for example, a semiconductor laser, an organic EL (ElectroLuminescence) element, an LED (Light Emitting Diode), or the like may be applied. A desirable example of the solid-state light emitting element 313 is an LED chip. The container 311 is a container which stores the solid-state light emitting element 313 and the sealing member 312. The container 311 also includes an electrode 314 which is a metal wiring for supplying electric power to the solid-state light emitting element 313. The solid-state light emitting element 313 and the electrode 314 are electrically connected to each other by a bonding wire 315.

The container 311 is formed from, for example, a ceramic, a metal, or a resin. As the ceramic forming the container 311, aluminum oxide, aluminum nitride, or the like may be exemplified. As the metal, for example, an aluminum alloy, an iron alloy, a copper alloy, or the like on a surface of which an insulating film is formed may be exemplified. As the resin, for example, a glass fiber reinforced epoxy resin or the like may be exemplified. For the container 311, a material having a relatively high light reflectance (for example, a light reflectance of 90% or greater) may be applied. In this case, the light emitted from the solid-state light emitting element 313 can be reflected by the surface of the container 311, and light retrieval efficiency of the light source 310 can be improved. In addition, an inner surface of the container 311 in which the solid-state light emitting element 313 is placed may be treated to increase the light reflectance.

The sealing member 312 is a sealing member which seals at least a portion of the solid-state light emitting element 313, the bonding wire 315, and the electrode 314. The fluorescent material 317 is desirably contained in the sealing member 312. The sealing member 312 is formed from, for example, a light transmissive resin containing the fluorescent material 317. Examples of the light transmissive resin include a silicone resin, an epoxy resin, and a urea resin, but the composition of the light transmissive resin is not particularly limited.

As the solid-state light emitting element 313, an LED chip which emits purple light having a light emission peak wavelength of 380 nm˜430 nm is desirably used. A purple LED chip forming the solid-state light emitting element 313 emits single light having the light emission peak wavelength of 380 nm˜430 nm. When the peak wavelength of the solid-state light emitting element 313 exceeds 430 nm, an absorbance of the fluorescent material 317 is rapidly reduced, and thus, an upper limit of the peak wavelength must be 430 nm. On the other hand, when the peak wavelength is shorter than 380 nm, the light emission efficiency of the solid-state light emitting element 313 is significantly reduced, and thus, a lower limit of the peak wavelength must be 380 nm.

The peak wavelength of the solid-state light emitting element 313 is particularly desirably 400 nm˜420 nm. When the peak wavelength is in this range, the light emission efficiency of the solid-state light emitting element 313 is high, and the absorbance of the fluorescent material is also high. Thus, a high light flux can be obtained from the light source 310. An example of the solid-state light emitting element 313 is a purple LED which uses an InGaN-based compound semiconductor. While the light emitted from the solid-state light emitting element 313 is absorbed by the fluorescent material 317 contained in the sealing member 312, when a part of the light transmits through the sealing member 312, the road light 100 desirably includes an optical member (optical element) which cuts the light, in particular, of the wavelength of 420 nm or shorter.

As the above-described optical member, for example, a long-pass filter which cuts light of a wavelength of 420 nm or shorter may be used. As the long-pass filter, a filter which can cut the light of the wavelength of 420 nm or shorter and which has a high transmissivity for light of the wavelength exceeding 420 nm is used. The long-pass filter can be attached to cover the surface of the light emitting unit 300. The light of the wavelength of 420 nm or shorter tends to attract insects. By cutting the light of the wavelength of 420 nm or shorter using the optical member, it becomes possible to suppress gathering of the insects on the road light 100.

The light source 310 desirably contains, as the fluorescent material 317, a blue fluorescent material 317b, a green fluorescent material 317g, and a red fluorescent material 317r. In this case, the purple light emitted from the solid-state light emitting element 313 is converted into the white light using the three fluorescent materials. That is, the white light is obtained by mixing the lights irradiated from the three fluorescent materials. According to the light source 310, a superior visibility and a uniform color tone are realized over the entire illuminati region. For example, a uniform and bright illumination space is obtained by the natural white light not only in the photopic vision environment immediately below the road light 100, but also in the peripheral portion of the illumination surface LA (refer to FIG. 1), and the visibility of various signs including the center line, and the white road line such as a pedestrian crosswalk can be significantly improved.

The white light emitted from the light source 310 may include the purple light of the solid-state light emitting element 313, but because the light of the solid-state light emitting element 313 is light of a low visual sensitivity, the light does not affect a tint of the white light. In other words, even when the light of the solid-state light emitting element 313 is included in the white light, a superior visibility and a uniform color tone can be obtained over the entire illumination region.

The blue fluorescent material 317b is not particularly limited in the light emission peak wavelength, but desirably has a peak wavelength of 440 nm˜480 nm, and is desirably a fluorescent material having a wavelength λh on a long wavelength side at a half value of the light emission peak of 480 nm˜500 nm. Here, the light emission peak refers to a maximum peak of the light emission spectrum, and the half value of the light emission peak refers to an intensity of 50% of the intensity of the peak. Of the wavelengths of the half values of the light emission peak, the wavelength on the short wavelength side is not particularly limited, but the wavelength λh on the long wavelength side is desirably 480 nm˜500 nm. In this case, a high S/P ratio is obtained, and white color having a high rendering property can be obtained.

In general, as the light emission wavelength becomes longer, the S/P ratio becomes higher and the Ra becomes lower. When the wavelength λh is shorter than 480 nm, the S/P ratio is reduced, and the action on the rod cell tends to be reduced. On the other hand, when the wavelength λh is longer than 500 nm, Ra is reduced, and viewing of coloration tends to be degraded.

The blue fluorescent material 317b may be any fluorescent material which absorbs the purple light of the solid-state light emitting element 313, and emits blue light satisfying the above-described conditions. Examples of the blue fluorescent material 317b include (Ba, Sr, Ca, Mg)₂SiO₄:Eu²⁺, BaMgAl₁₀O₁₇:Eu²⁺, Sr₁₀(PO₄)₆Cl₂:Eu²⁺, (Sr, Ba, Ca)₁₀(PO₄)₆Cl₂:Eu²⁺, and the like.

The green fluorescent material 317b is desirably a fluorescent material having a light emission peak wavelength of 530 nm˜550 nm, and a spectrum half width of greater than or equal to 50 nm. When the light emission peak wavelength and the spectrum half width are in these ranges, a high S/P ratio and a sufficient light flux can be obtained. As the light emission peak wavelength of the green fluorescent material 317g becomes longer, the lumen equivalence is increased, and the S/P ratio is reduced. For example, when the light emission peak wavelength is shorter than 530 nm, it may not be possible to obtain a sufficient light flux. On the other hand, when the light emission peak wavelength is longer than 550 nm, it may not be possible to obtain a sufficient S/P ratio.

Here, the spectrum half width (or “half width”) refers to an entire width of the peak at a value corresponding to 50% of the intensity of the maximum peak of the light emission spectrum. When the half width of the light emission peak of the green fluorescent material 317g is increased, Ra tends to be increased. For example, when the half width Ra is smaller than 50 nm, Ra is reduced, and the viewing of the coloration tends to be degraded.

The green fluorescent material 317g may be any fluorescent material which absorbs the purple light of the solid-state light emitting element 313 and irradiates the green light satisfying the above-described conditions. Examples of the green fluorescent material 317g include β-sialon fluorescent material, CaSc₂O₄:Eu²⁺, (Ba, Sr)₂SiO₄:Eu²⁺, BaMgAl₁₀O₁₇:Eu^{2+,} Mn²⁺, Ba₃Si₆O₁₂N₂:Eu²⁺, (Si, Al)₆(O, N)₈:Eu²⁺, and the like.

The red fluorescent material 317r is desirably a fluorescent material having a light emission peak wavelength of 610 nm˜625 nm. When the light emission peak wavelength is within this range, a sufficient light flux can be obtained, and a white light also having a high rendering property can be obtained. As the light emission peak wavelength of the red fluorescent material 317r becomes longer, Ra becomes longer and the lumen equivalence becomes lower. For example, when the light emission peak wavelength is shorter than 610 nm, Ra is reduced, and the viewing of the coloration tends to be degraded. On the other hand, when the light emission peak wavelength is longer than 625 nm, it may not be possible to obtain a sufficient light flux.

The red fluorescent material 317r may be any fluorescent material which absorbs the purple light of the solid-state light emitting element 313 and irradiates the red light satisfying the above-described conditions. Examples of the red fluorescent material 317r include an activated oxide of Eu³⁺ fluorescent material, CaAlSiN₃:Eu²⁺, (Ca, Sr)AlSiN₃:Eu²⁺, Ca₂Si₅N₈:Eu²⁺, (Ca, Sr)₂Si₅N₈:Eu²⁺, and the like.

The white light emitted from the light source 310; that is, the white light having the wavelength converted by the fluorescent material 317, has, as described above, the correlated color temperature of 5000 K˜65000 K, the Duv within ±10, the S/P ratio of greater than or equal to 2.0, and the lumen equivalence, calculated by the above-described Equation 1, of greater than or equal to 3001 m/W. According to this white light, it is possible to brightly illuminate the entire illumination region, and a superior visibility can be obtained for both the central vision and the peripheral vision. In addition, the white light is natural white light having a small blue tint and no awkward feeling.

When the correlated color temperature of the white light is increased, the white line on the road 200 and the white texts of the signs or the like becomes emphasized in white and becomes more visible, but when the color temperature is increased too much, the light tends to include the blue tint. Thus, the color temperature is desirably 5000 K˜6500 K, and more desirably 5200 K˜6000 K. For example, in locations where fog tends to occur frequently, the blue component can be reduced so that scattering of the illumination is suppressed and the field of view during the fog can be improved. When the Duv exceeds the range of ±10, the white light tends to include green tint or red tint, and awkward feeling tends to be caused more easily. The Duv is desirably within ±5. In this case, more natural white light can be obtained, and the white of the road white line or the like can be emphasized and can be easily viewed.

The color deviation is a deviation from a color temperature on a black body locus. The S/P ratio (RSP) can be calculated based on Equation 2 described below, when, for example, V(λ) is a spectral luminosity function of the light source 310 in the photopic vision, and V′(λ) is a spectral luminosity function in the scotopic vision.

$$LE = \frac{{K}^{′} \int {V}^{′} ( λ ) {Φ}_{e} ( λ ) d λ}{{K}^{′} \int V ( λ ) {Φ}_{e} ( λ ) d λ} \qquad ( Equation 2 )$$

In Equation 2, K represents a maximum visual sensitivity in photopic vision (=6831 m/W), K′ represents the maximum visual sensitivity in scotopic vision (=16991 m/W), and Φₑ(λ) is a spectral total radiant flux of the light source 310.

As the S/P ratio of the white light is increased, the advantage of bright view under the mesopic vision state is increased, and the advantage can be felt when the S/P ratio is greater than or equal to 2.0. The lumen equivalence calculated by Equation 1 described above is an index for evaluating the visibility in the photopic vision per equivalence energy, and as the value of the lumen equivalence is increased, the equipment efficiency is increased and the brightness of the central vision can be achieved with a smaller electric power. With the lumen equivalence of greater than or equal to 3001 m/W, sufficient brightness of the central vision can be realized.

In other words, light having a large lumen equivalence can be interpreted as having a higher visibility for the same light energy in the photopic vision; that is, light which can be easily recognized by the cone cell. Further, the illumination having a large lumen equivalence is an illumination which can be easily recognized by the cone cell also in the mesopic vision. Because of this, the light emitted from the light source 310 is light having a large proportion of light which can be easily recognized by the cone cell even in the mesopic vision. Thus, the light emitted from the light source 310 is light having a high usage efficiency of light energy because the light can be brightly felt in the central vision and the peripheral vision for the driver and the pedestrian in the mesopic vision.

As described above, according to the road light 100 which is the outdoor illumination apparatus having the light source 310, a superior visibility and a uniform color tone can be obtained over the entire illumination region while having a simple structure which does not require a complicated optical design. In the road light 100, the central vision and the peripheral vision can both be brightly felt, without separately illuminating the roadway 210 and the passenger way 220. For the driver of the traveling vehicle, the visibility for the status of the roadway 210, the status on the side of the road 200, and the pedestrian on the pedestrian way 220, or the like can be improved. In addition, visibility of various signs including the road white line can be improved. For the pedestrians, because the white light which can be recognized as bright at the central vision illuminates the periphery thereof, the visibility of the region where the pedestrian stands, which is viewed by the central vision, can be improved, and the safety during the walk can be improved. In addition, spatially uniform white light is illuminated between the roadway 210 and the pedestrian way 220, and, thus, an illumination space having no color irregularities, uniform color tones, and no awkward feeling can be realized.

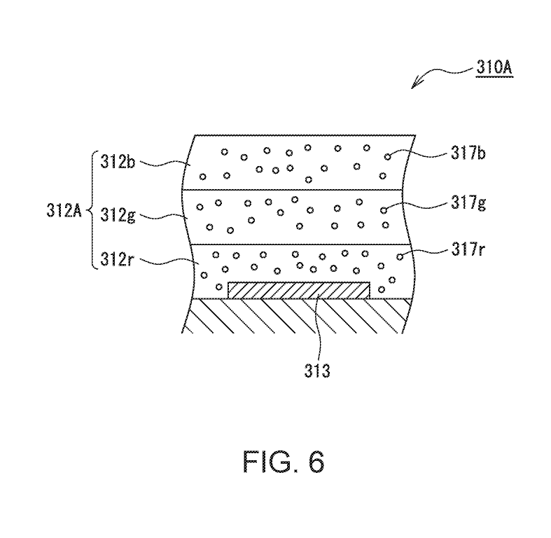

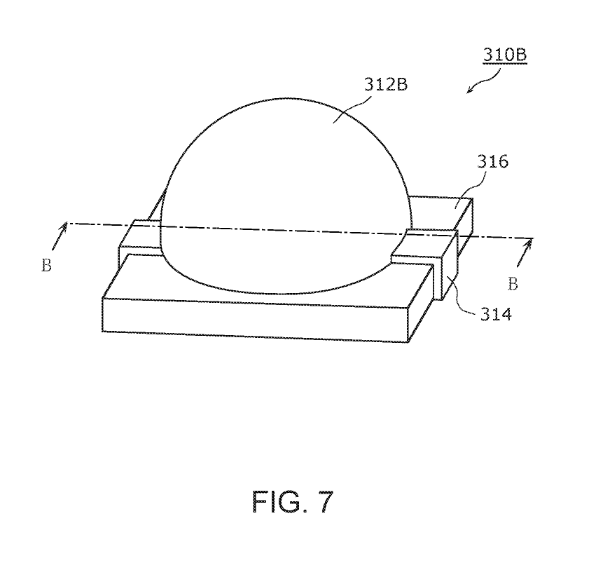

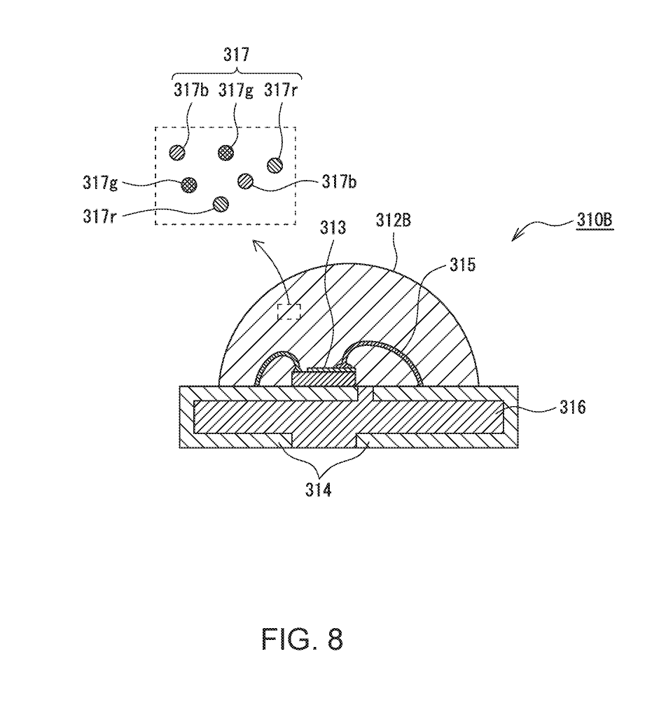

The light source applied to the outdoor illumination apparatus such as the road light 100 is not limited to the light source 310, and may alternatively be a light source 310A exemplified in FIG. 6 or a light source 310B exemplified in FIGS. 7 and 8.

In the light source 310, the plurality of fluorescent materials are present in a randomly distributed state in the sealing member 312, but the placement of the fluorescent materials is not limited to such a configuration. For example, the light source may include, as the fluorescent material, a first fluorescent material and a second fluorescent material which irradiates light of a longer wavelength than the first fluorescent material, and the second fluorescent material may be placed nearer to the solid-state light emitting element than the first fluorescent material. When a plurality of fluorescent materials are mixed and used, the fluorescent material which emits light of a longer wavelength side (second fluorescent material) may re-absorb the light emitted from the other fluorescent material (first fluorescent material). With the above-described arrangement, however, such re-absorption can be suppressed, and light emission efficiency can be improved.

FIG. 6 is a cross-sectional diagram enlarging a part of the light source 310A. As exemplified in FIG. 6, the light source 310A differs from the light source 310 in that the light source 310A includes a sealing member 312A having a three-layer structure. The sealing member 312A includes, from the side of the solid-state light emitting element 313 in this order, a first sealing layer 312r containing the red fluorescent material 317r, a second sealing layer 312g containing the green fluorescent material 317g, and a third sealing layer 312b containing the blue fluorescent material 317b. Of the three fluorescent materials 317, the red fluorescent material 317r emits light of the longest wavelength. Therefore, by placing the first sealing layer 312r containing the red fluorescent material 317r near the solid-state light emitting element 313, the above-described re-absorption can be suppressed, and the light emission efficiency can be improved.

Further, as the green fluorescent material 317g emits light of a wavelength which is the next longest after the red fluorescent material 317r, the second sealing layer 312g containing the green fluorescent material 317g is desirably placed nearer to the solid-state light emitting element 313 than is the third sealing layer 312b containing the blue fluorescent material 317b. For light transmissive resins forming the layers of the sealing member 312A, the same resin may be used for all layers such as the silicone resin.

FIG. 7 is a perspective diagram of the light source 310B, and FIG. 8 is a cross-sectional diagram along a line BB of FIG. 7. As exemplified in FIGS. 7 and 8, the light source 310B includes a substrate 316, and the solid-state light emitting element 313 mounted over the substrate 316. The substrate 316 is a substrate having a wiring region in which the electrode 314 is provided. The substrate 316 may be any of a metal-based substrate, a ceramic substrate, a resin substrate, or the like. In addition, for the substrate 316, a substrate having a high light reflectance may be applied. With the use of the substrate having the high light reflectance, it becomes possible to reflect the light of the solid-state light emitting element 313 by the surface of the substrate 316, and light retrieval efficiency of the light source 310B can be improved. As such a substrate, for example, a white ceramic substrate having a base material of alumina may be exemplified.

A sealing member 312B of the light source 310B is formed in a dome shape to have a radius of curvature over the substrate 316, and a cross-sectional shape of the sealing member 312B is approximately semi-circular. The sealing member 312B formed in the dome shape functions as a lens, and can collect light irradiated from the fluorescent material 317. A sealing member 312B is a dome-shaped cover which seals solid-state light emitting element. Here, by changing the radius of curvature of the sealing member 312B, it is possible to adjust the white light emitted from the road light having the light source 310b to a desired illumination angle. With the use of the sealing member 312B, for example, it becomes possible to illuminate the road 200 with a desired illumination range without separately providing, for example, a lens or the like.

Examples (Examples 1 and 2) of light emission spectra of white light emitted from the light source of the outdoor illumination apparatus according to the present disclosure will now be described. In addition, Comparative Examples 1 and 2 are also described.

### Example 1

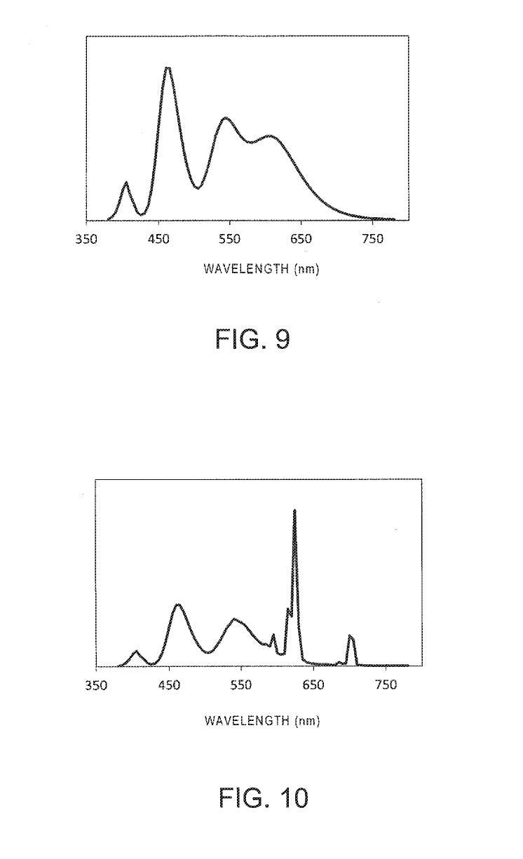

FIG. 9 is a diagram showing a light emission spectrum of a light source A of Example 1. The light source A has a structure similar to that of the light source 310, and includes an LED having a light emission peak at a wavelength of 405 nm, and the following three fluorescent materials. The three fluorescent materials were uniformly dispersed in a silicone resin forming the sealing member.

Blue fluorescent material: Silicate fluorescent material, (Ba, Sr, Ca, Mg)₂SiO₄:Eu²⁺
Green fluorescent material: β-sialon fluorescent material
Red fluorescent material: nitride fluorescent material, (Ca, Sr)AlSiN₃:Eu²⁺
The mixture amounts of the fluorescent materials were adjusted so that the correlated color temperature was 5500 K.

The Duv, the Ra, the S/P ratio, and the lumen equivalence calculated by Equation 1 of the white light emitted from the light source A were as follows.

### Duv: 0

### Ra: 87

S/P ratio: 2.1
Lumen equivalence: 3001 m/W

### Example 2

FIG. 10 is a diagram showing a light emission spectrum of a light source B of Example 2. The light source B has the same LED and the same structure as the light source A. The silicone resin forming the sealing member of the light source B contains the fluorescent materials described below in a uniformly dispersed state.

Blue fluorescent material: Silicate fluorescent material, (Ba, Sr, Ca, Mg)₂SiO₄:Eu²⁺
Green fluorescent material: β-sialon fluorescent material
Red fluorescent material: Activated oxide of Eu³⁺ fluorescent material, La₂O₂S:Eu³⁺
The mixture amounts of the fluorescent materials were adjusted so that the correlated color temperature was 5500 K.

The Duv, the Ra, the S/P ratio, and the lumen equivalence calculated by Equation 1 described above of the white light emitted from the light source B were as follows.

### Duv: 0

### Ra: 92

S/P ratio: 2.2
Lumen equivalence: 3001 m/W

### Comparative Example 1

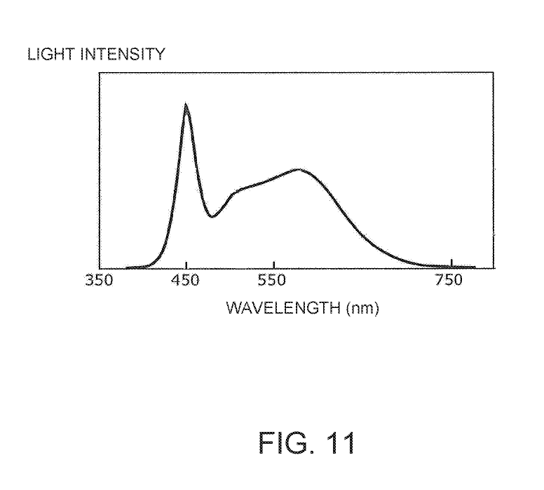

FIG. 11 is a diagram showing a light emission spectrum of a light source X of Comparative Example 1. The light source X has a structure similar to that of the light source 310, and includes a blue LED having a light emission peak at a wavelength of 450 nm, and two fluorescent materials described below. The two fluorescent materials were uniformly dispersed in a silicone resin which forms the sealing member.

Green fluorescent material: Lu₃Al₅O₁₂:Ce³⁺
Red fluorescent material: Nitride fluorescent material, (Ca, Sr) AlSiN₃:Eu²⁺
The mixture amounts of the fluorescent materials were adjusted such that the correlated color temperature was 6000 K.

The Duv, the Ra, and the S/P ratio of the white light emitted from the light source X were as follows.

### Duv: 0

### Ra: 80

S/P ratio: 2.2

### Comparative Example 2

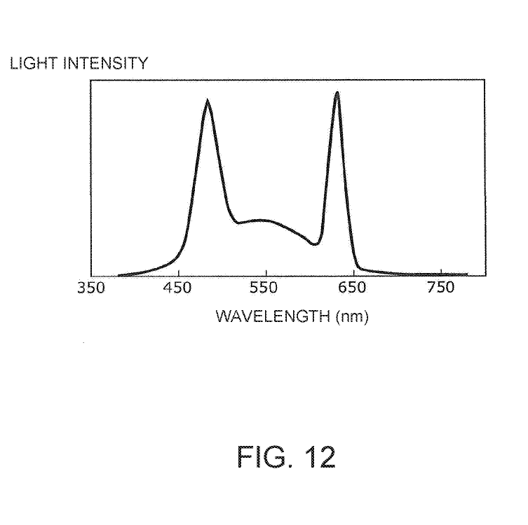

FIG. 12 is a diagram showing a light emission spectrum of a light source Y of Comparative Example 2. The light source Y has a structure similar to that of the light source 310, and includes a blue-green LED having a light emission peak at a wavelength of 480 nm, a red LED having a light emission peak at a wavelength of 630 nm, and the following fluorescent material. The fluorescent material was uniformly dispersed in the silicone resin forming the sealing member.

Green fluorescent material: Y₃Al₅O₁₂:Ce³⁺
The amount of mixture of the fluorescent material was adjusted so that the correlated color temperature was 5500 K.

The Ra and the S/P ratio of the white light emitted from the light source Y were as follows.

### Ra: 58

S/P ratio: 2.9

According to the outdoor illumination apparatuses using the light sources A and B having the light emission spectra of FIGS. 9 and 10, respectively, under the mesopic vision environment, both the central vision and the peripheral vision can be perceived as bright, a color reproducibility over the entire illumination region is high, and a superior visibility and a uniform color tone can be obtained. In the light emission spectra, light of LED having a peak at the wavelength of 405 nm appears, but the visual sensitivity for the light is low, and the light does not affect the tint of the white light.

On the other hand, in the outdoor illumination apparatus which uses the light source X showing the light emission spectrum of FIG. 11, the white light is obtained by a combination of the blue light of the blue LED and the green light and the red light of the fluorescent materials which wavelength-convert a part of the blue light. In this case, because the orientation differs between the blue light emitted from the LED and having a directionality, and yellow light (red light+green light) irradiated in all directions from the fluorescent materials, the light at an outer peripheral portion of the range in which the white light is illuminated becomes a white light having a large amount of a yellow light component and having a relatively low color temperature. Because of this, under the mesopic vision, the degree of action on the rod cell is reduced, and the visibility at the outer peripheral portion of the illuminated range is reduced. Therefore, for example, a range which can be viewed brightly by the driver of the traveling vehicle may be limited, or the optical design of the illumination equipment becomes complicated in order to prevent such white light from being illuminated onto the pedestrian way.

In the outdoor illumination apparatus which uses the light source Y showing the light emission spectrum of FIG. 12, a problem similar to that of the apparatus using the light source X exists. In addition, because the white light of the light source Y has the Ra of 58, the color reproducibility is low, and there is a possibility that the driver and the pedestrian misunderstand the color of the signs or the like.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A light source comprising:
a solid-state light emitting element that emits light having a light emission peak wavelength of 380 nm˜430 nm; and
a fluorescent material that absorbs the light emitted from the solid-state light emitting element and irradiates white light, wherein
the white light includes:
a correlated color temperature of 5000 K˜6500K,
a color deviation within ±10,
an S/P ratio, which is a ratio between a light flux in a scotopic vision and a light flux in a photopic vision, of greater than or equal to 2.0, and
a lumen equivalence (LE), which is calculated by Equation 1, of greater than or equal to 3001 m/W
$$LE = \frac{K {\int }_{380}^{780} V ( λ ) {Φ}_{e} ( λ ) d λ}{{\int }_{380}^{780} {Φ}_{e} ( λ ) d λ} \qquad ( Equation 1 )$$
wherein K represents a maximum visual sensitivity, which is 6831 m/W, V(λ) represents a standard visual sensitivity, and Φₑ(λ) represents an illumination spectral distribution.

2. The light source according to claim 1, wherein
an average rendering index of the white light is greater than or equal to 80.

3. The light source according to claim 1, wherein
the fluorescent material includes:
a blue fluorescent material having a light emission peak wavelength of 440 nm˜480 nm, and a wavelength on a longer wavelength side at a half value of a light emission peak intensity of 480 nm˜500 nm;
a green fluorescent material having a light emission peak wavelength of 530 nm˜550 nm and a spectrum half width of greater than or equal to 50 nm; and
a red fluorescent material having a light emission peak wavelength of 610 nm˜625 nm.

4. The light source according to claim 1, wherein
the fluorescent material includes a first fluorescent material and a second fluorescent material,
the second fluorescent material irradiates light of a longer wavelength than the first fluorescent material, and
the second fluorescent material is placed nearer to the solid-state light emitting element than the first fluorescent material.

5. An outdoor illumination apparatus comprising the light source according to claim 1.

6. The outdoor illumination apparatus according to claim 5, further comprising an optical element which cuts light of a wavelength of shorter than or equal to 420 nm.

7. The outdoor illumination apparatus according to claim 5, wherein
the light source is positioned at a height of 5 m˜15 m from a surface, and illuminates the white light onto the surface.

8. The light source according to claim 3, wherein
the blue fluorescent material is a silicate fluorescent material,
the green fluorescent material is a β-sialon fluorescent material, and
the red fluorescent material is a nitride fluorescent material or an activated oxide of Eu³⁺ fluorescent material.

9. The light source according to claim 1, wherein
the solid-state light emitting element is a light emitting diode.

10. The outdoor illumination apparatus according to claim 5, wherein the outdoor illumination apparatus is a street light placed on a street.

11. The light source according to claim 1, wherein a light emission peak wavelength of light emitted by the solid-state light emitting element is 400 nm˜420 nm.

12. The light source according to claim 1, wherein the correlated color temperature of the white light is 5200 K˜6000 K.

13. The light source according to claim 1, further comprising:
a dome-shaped cover, wherein the cover seals the solid-state light emitting element.
